(19) United States
(12) Patent Application Publication
(10) Pub. No.: US 2014/0009186 A1
(43) Pub. Date: Jan. 9, 2014

(54) ELECTRIC MACHINE

(71) Applicants: Thomas Kässner, Dresden (DE); Alessandro Fasolo, Vipiteno (IT); Otto Pabst, Rio Di Pusteria (IT)

(72) Inventors: Thomas Kässner, Dresden (DE); Alessandro Fasolo, Vipiteno (IT); Otto Pabst, Rio Di Pusteria (IT)

(73) Assignee: Wilic S.A.R.L., Luxembourg (LU)

(21) Appl. No.: 13/990,725

(22) PCT Filed: Dec. 5, 2011
(86) PCT No.: PCT/IB11/55469

§ 371 Date: Sep. 10, 2013

(30) Foreign Application Priority Data
Dec. 3, 2010 (IT) MI2010A002246

(51) Int. Cl. G01R 33/12

(52) U.S. Cl. CPC G01R 33/1215
USPC 324/765.01

(57) ABSTRACT

A method of determining the magnetization level of permanent magnets of an electric machine, whereby a probe winding is placed in an electric machine having a stator with a plurality of stator winding, and a rotor with a plurality of permanent magnets; the probe winding is fixed with respect to the stator and links a magnetic flux produced by the permanent magnets; the rotor is rotated at an angular speed; an induced electric quantity is determined at terminals of the probe winding in response to passage of the permanent magnets; and the magnetization level of the permanent magnets is determined on the basis of the induced electric quantity detected.

### PRIORITY CLAIM

This application is a national stage application of PCT/IB2011/055469, filed on Dec. 5, 2011, which claims the benefit of and priority to Italian Patent Application No. MI2010A 002246, filed on Dec. 3, 2010, the entire contents of which are each incorporated by reference herein.

### BACKGROUND

As is known, the efficiency of a rotary, permanent-magnet electric machine, such as a wind turbine alternator, is strongly affected by its magnetization level, which may vary over time. During operation of the machine, the original magnetization condition may be altered, for example, by breakages, exposure to high temperature or intense electromagnetic fields, or other factors.

It is also important to bear in mind that permanent magnets are normally magnetized before the machine is installed, and often even before the machine is assembled; and assembly and installation may alter magnetization of the permanent magnets, thus greatly affecting performance of the machine by the time the machine is ready to go into operation.

In fact, it is not unusual for the efficiency of the electric machine to be insufficient or less than predicted.

On the other hand, certain currently used methods of determining the magnetization of permanent magnets are relatively complicated and expensive, such as normally involving dismantling the machine and often also the magnets.

As a result, magnetization of the permanent magnets cannot be checked as often as it should.

Maintenance is therefore not organized properly, the machine is not run to its full potential, and reassembling the magnets involves the same risks as prior to installation of the machine. That is, the risk of altering the magnetization of even perfectly functioning magnets.

PCT Published Patent Application No. WO 2008/116463 discloses an electric machine having a magnetization sensor fixed to the stator and arranged to link a magnetic flux produced by permanent magnets of the rotor. A measuring means detects currents induced in the magnetization sensor in response to passage of the permanent magnets during rotation of the rotor. A processing unit determines the magnetization level of the permanent magnets on the basis of the induced currents detected when the rotor is rotating.

### SUMMARY

The present disclosure relates to an electric machine.

It is an advantage of the present disclosure to provide an electric machine, configured to eliminate certain of the drawbacks of known electric machines.

According to one aspect of the present disclosure, there is provided an electric machine including a stator having a plurality of stator windings, a rotor having a plurality of permanent magnets, and a probe winding fixed with respect to the stator and located close to the rotor to link a magnetic flux produced by at least one of the permanent magnets. The electric machine of this embodiment includes a drive member configured to rotate the rotor at an angular speed, and a detector configured to detect an induced electric quantity at at least one terminal of the probe winding, said induced electric quantity detected in response to passage of the permanent magnets close to the probe winding. The electric machine of this embodiment includes a processing unit configured to: (i) determine a magnetization level of the permanent magnets based on the induced electric quantity detected when the rotor is rotating, (ii) set the stator windings to an open-circuit condition, and (iii) determine the magnetization level of the permanent magnets based on the induced electric quantity detected when the rotor is rotating with the stator windings in the open-circuit condition. The electric machine of this embodiment includes a switch connected to the processing unit and controllable to alternatively: (i) connect the stator windings to at least one external electric equipment, and (ii) set the stator windings to the open-circuit condition.

Additional features and advantages are described in, and will be apparent from the following Detailed Description and the figures.

### BRIEF DESCRIPTION OF THE DRAWINGS

A number of non-limiting embodiments of the present disclosure will be described by way of example with reference to the accompanying drawings, in which:

FIG. 1 shows a partly sectioned side view, with parts removed for clarity, of a wind turbine comprising an electric machine in accordance with one embodiment of the present disclosure;

FIG. 2 shows a larger-scale, partly sectioned side view, with parts removed for clarity, of a detail in FIG. 1;

FIG. 3 shows a simplified front view of a portion of the FIG. 1 electric machine sectioned along line III-III in FIG. 2;

FIG. 4 shows a simplified block diagram of the FIG. 1 electric machine;

FIG. 5 shows a simplified block diagram of a component part of the FIG. 1 electric machine;

FIG. 6 shows a flow chart of steps in a method of determining the magnetization level of permanent magnets of an electric machine in accordance with one embodiment of the present disclosure;

FIG. 7 shows a simplified block diagram of an electric machine in accordance with a different embodiment of the present disclosure;

FIG. 8 shows a simplified block diagram of an electric machine in accordance with another embodiment of the present disclosure;

FIG. 9 shows a simplified front cross section of a portion of an electric machine in accordance with another embodiment of the present disclosure; and

FIG. 10 shows an enlarged, three-quarter view in perspective of a detail of the FIG. 9 electric machine.

### DETAILED DESCRIPTION

In the example embodiments of the disclosure described below, reference is made to permanent-magnet electric generators used in wind turbines, in which the disclosure may be used to particular advantage. This, however, shall in no way be construed as a limitation of the disclosure, which applies to any rotary, permanent-magnet electric machine, particularly synchronous generators, coupled to any type of motor (especially gas, steam, and hydraulic turbines) and electric motors.

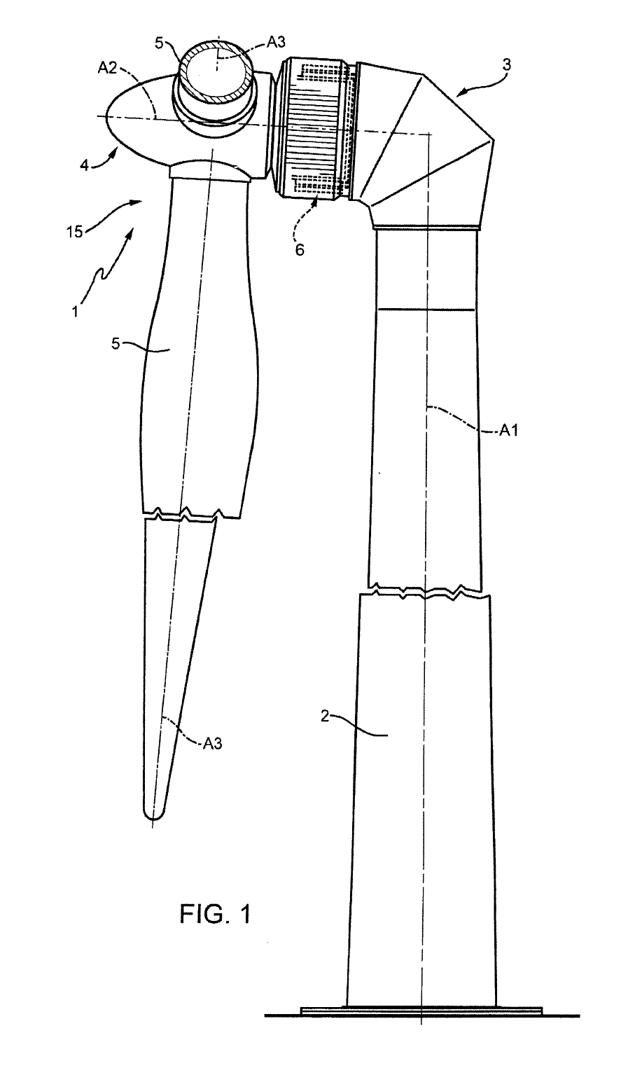

Referring now to the example embodiments of the present disclosure illustrated in FIGS. 1 to 10, number 1 in FIG. 1 indicates as a whole a wind turbine comprising a pylon 2, a nacelle 3, a hub 4, a plurality of (in the example shown, three) blades 5, and an electric machine 6.

Blades 5 are fitted to hub 4, which in turn is fitted to nacelle 3. Nacelle 3 is fitted to pylon 2 to rotate about an axis A1 and position blades 5 facing the wind; and hub 4 is mounted to rotate about an axis A2 with respect to nacelle 3.

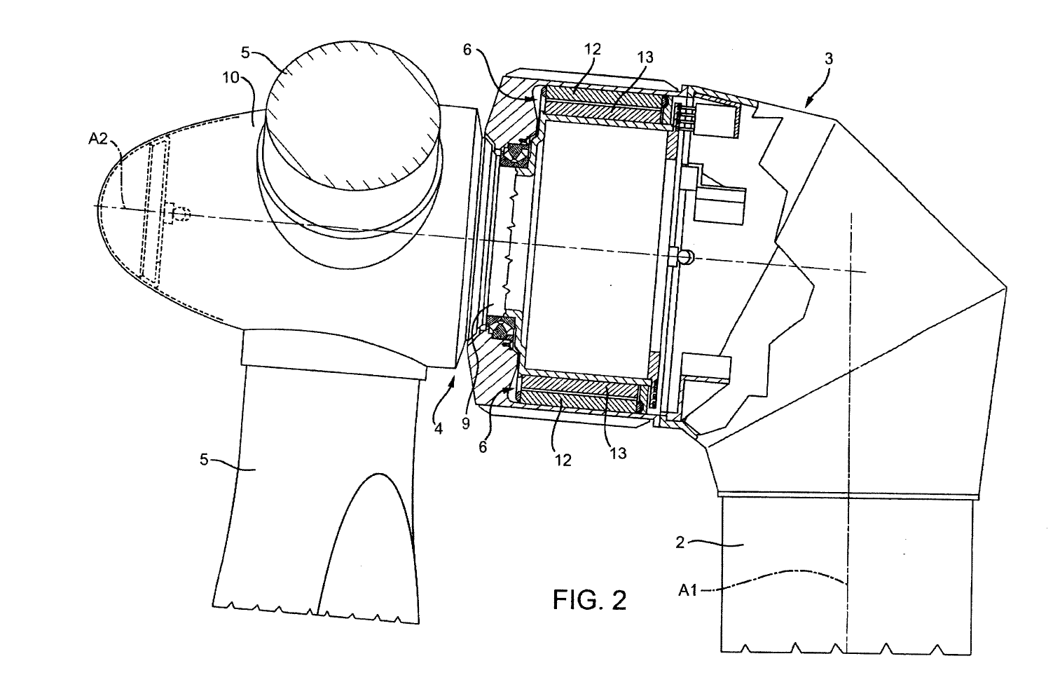

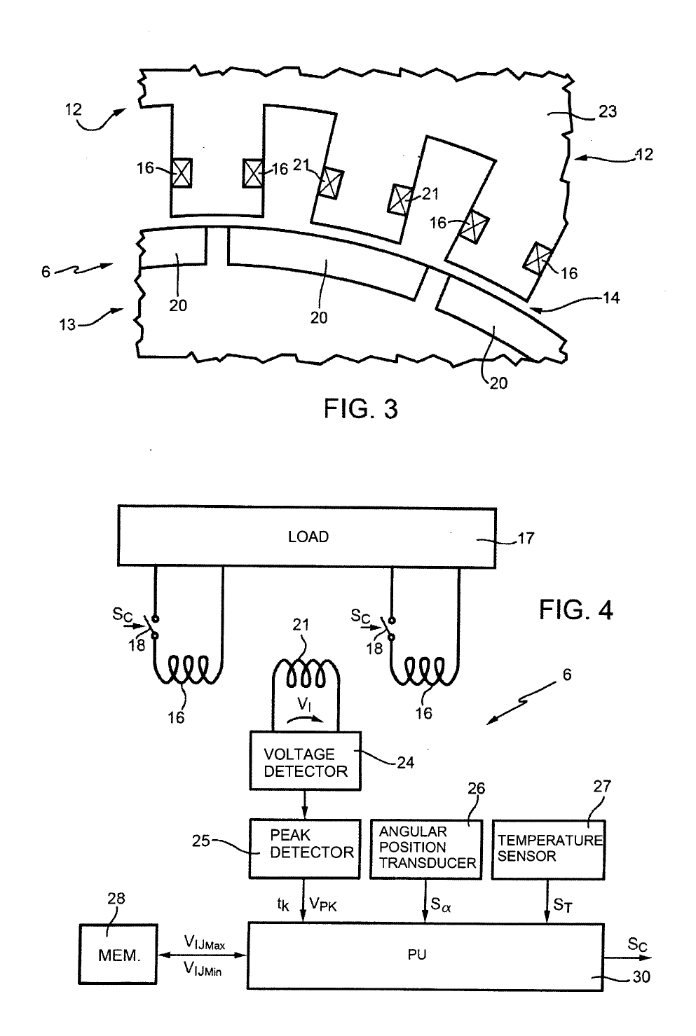

With reference to FIGS. 2 and 3, hub 4 comprises a hollow shaft 9 and a body 10 connected rigidly to each other. Hollow shaft 9 is fitted to nacelle 3 and, in the embodiment described, is connected directly to electric machine 6.

In the embodiment described, electric machine 6 is a synchronous generator, and comprises a stator 12 and a rotor 13 separated by an annular gap 14. Stator 12 forms a portion of nacelle 3; rotor 13 is fixed directly to hollow shaft 9; and rotor 13, hub 4, and blades 5 define a rotary assembly 15, which rotates with respect to nacelle 3 about axis A2, and is rotated by the wind about axis A2 at an angular speed Ω.

As shown in FIGS. 3 and 4, stator 12 has a plurality of stator windings 16, each connectable selectively to an electric load 17 by a respective switch 18. When switches 18 are open, the corresponding stator windings 16 are set to an open-circuit condition, isolated from load 17, which may, for example, be an electric power distribution network, to which user devices (not described in detail), are connected.

Rotor 13 has a plurality of permanent magnets 20, which face stator 12 across gap 14, are configured and arranged to produce a substantially sinusoidal magnetic field along a circle concentric with axis A2 of rotor 13, and may be magnetized radially or tangentially.

A probe winding 21 is housed between stator 12 and rotor 13, is fixed with respect to stator 12, and, in one embodiment, is fitted to a pole piece 22 projecting towards rotor 13 from a casing 23 of stator 12, and located between two adjacent stator windings 16.

Probe winding 21 is oriented to link the magnetic flux generated by permanent magnets 20 passing close to probe winding 21.

Electric machine 6 also comprises a voltage detector 24, a peak detector 25, an angular position transducer 26, a temperature sensor 27, and a memory 28. In one embodiment, electric machine includes a non-volatile processing unit 30.

Voltage detector 24 is connected to terminals of probe winding 21 to detect an induced voltage VI in response to passage of permanent magnets 20. Given the usual shape and arrangement of permanent magnets 20, induced voltage V1 is sinusoidal when rotor 13 rotates at constant angular speed a Ω.

Peak detector 25 is connected to voltage detector 24 to determine peak values VPK and corresponding peak instants tK of induced voltage VI at each half-wave. Depending on the configuration of electric machine 6, peak values VPK of induced voltage VI are caused by the magnetic field generated by one or a pair of permanent magnets 20. For the sake of simplicity, unless otherwise stated, reference is made in the following description to peak values VPK of induced voltage VI caused by the magnetic field generated by one permanent magnet 20, it being understood, however, that the same also applies to peak values VPK of induced voltage VI caused by the magnetic field generated by a pair of permanent magnets 20.

Angular position transducer 26, which, in the embodiment described, is an absolute encoder, determines the angular position a of rotor 13 with respect to a reference angular position αREF, and supplies a corresponding angular position signal Sα to processing unit 30.

Temperature sensor 27 is located close to rotor 13, in an angular position substantially corresponding to probe winding 21, and supplies processing unit 30 with a temperature signal ST indicating a temperature T of rotor 13. Temperature sensor 27 may, for example, be a thermoresistive sensor or a thermocouple; and, in one embodiment (not shown), temperature sensors are also installed on the rotor, close to respective permanent magnets.

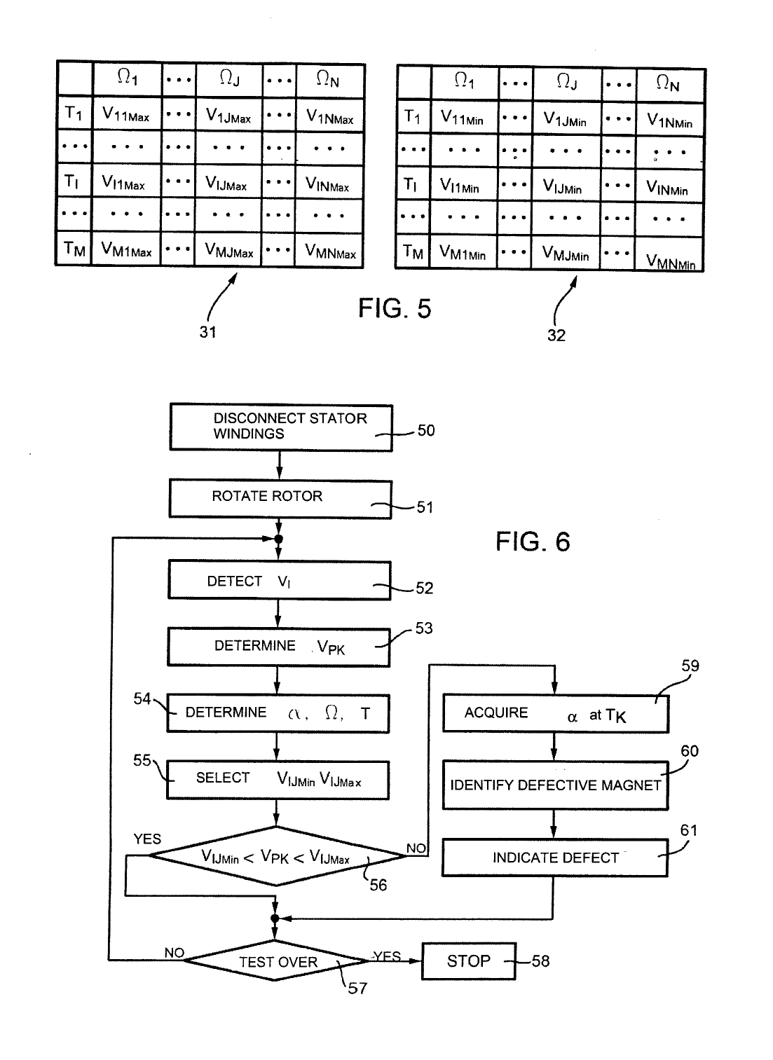

Memory 28 stores maximum values VJKMax and minimum values VJKMin of induced voltage VI as a function of the temperature T and angular speed Ω of rotor 13 (e.g., organized in tables 31, 32, as shown in FIG. 5). Maximum values VIJMax and minimum values VIJMin represent maximum and minimum acceptance thresholds for peak values VPK of induced voltage VI in normal operating conditions. In other words, when the magnetization level of the permanent magnet 20 passing close to probe winding 21 is appropriate, the peak values VPK of induced voltage VI range between maximum value VIJMax and minimum value VIJMin corresponding to the current temperature and angular speed Ω of rotor 13. Conversely, when a peak value VPK of induced voltage VI is below minimum value VIJMin or above maximum value VIJMax in the current temperature and angular speed Ω conditions, a magnetization defect, directly attributable to one or a pair of permanent magnets 20, depending on the structure of rotor 13, is detected. Depending on the structure of rotor 13, it is therefore possible to immediately identify the defective permanent magnet 20 or at least a subset (pair) of permanent magnets 20 including the defective permanent magnet 20.

Processing unit 30 receives angular position signal SΩ and temperature signal ST, is connected to memory 28 to access tables 31 and 32, and controls switches 18, utilizing a control signal Sc, to connect stator windings 16 to electric load 17, or set stator windings 16 to an open-circuit condition.

To determine the magnetization level of permanent magnets 20, processing unit 30 opens switches 18 to set stator windings 16 to the open-circuit condition and disconnect electric load 17, as shown in FIG. 6 (block 50); and rotor 13 is then rotated. In one embodiment, rotor 13 is rotated at constant angular speed Ω (block 51).

With rotor 13 rotating, induced voltage VI is detected (block 52), and its absolute peak values VPK detected by peak detector 25 (block 53).

Using angular position signal Sα and temperature signal ST, processing unit 30 determines the angular position α, angular speed Ω, and temperature T of rotor 13 (block 54), and then accesses memory 28 to extract from tables 31 and 32 a maximum value VIJMax and minimum value VIJMin corresponding to angular speed Ω and temperature T (block 55). In one embodiment, maximum value VIJMax and minimum value VIJMin are updated whenever a new peak value VPK of induced voltage VI is determined. In other embodiments (not shown), however, maximum value VIJMax and minimum value VIJMin may be read from memory 28 at a predetermined rate, or only following variations in angular speed Ω and/or temperature T of rotor 13.

Processing unit 30 then compares the last peak value VPK with the maximum value VIJMax and minimum value VIJMin extracted from tables 31 and 32 (block 56).

If the peak value VPK ranges between the selected maximum value VIJMax and minimum value VIJMin (YES output of block 56), processing unit 30 determines whether the magnetization test is completed (block 57), and, if the magnetization test is completed (YES output of block 57), processing unit terminates the procedure (block 58). The test may be considered completed, for example, after a given or designated time interval or after a given or designated plurality of turns of rotor 13. If the test is not yet completed (NO output of block 57), acquisition of induced voltage VI continues (block 52), and the procedure is repeated as described above up to comparison of the last peak value VPK of induced voltage VI with the maximum value VIJMax and minimum value VIJMin selected from tables 31 and 32.

If the peak value VPK of induced voltage VI is above maximum value VIJMax or below minimum value VIJMin (NO output of block 57), processing unit 30 acquires the angular position α of rotor 13 at a peak instant tK corresponding to the peak value VPK that has failed the test (block 59), and identifies the defective permanent magnet 20 by comparing the current angular position α of rotor 13 and the angular position of probe winding 16 with respect to the axis of rotor 13 (block 60). Finally, processing unit 30 indicates the presence and location of a defective permanent magnet 20 (block 61).

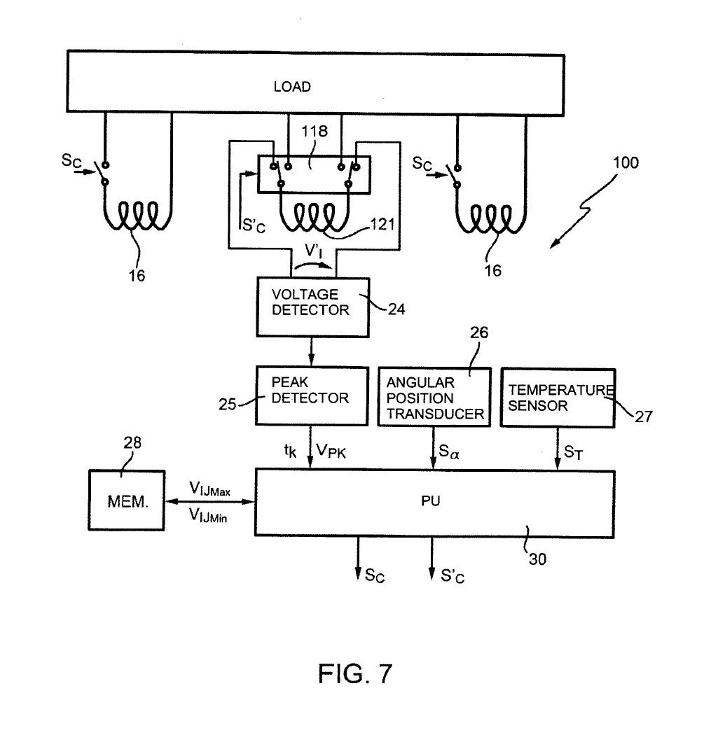

In a different embodiment of the disclosure, shown in FIG. 7, one of stator windings 16 of an electric machine 100 is used as a probe winding and it is indicated with reference numeral 121. In this case, the probe winding 121 is connectable to load 17 or to voltage detector 24 by a selector 118 controlled by processing unit 30 utilizing a control signal Sc′. During normal operation of electric machine 6, selector 118 connects probe winding 121 to load 17, and probe winding 121 operates as a normal stator winding 16. To test magnetization, processing unit 30 switches selector 118 to connect probe winding 16 to voltage detector 24.

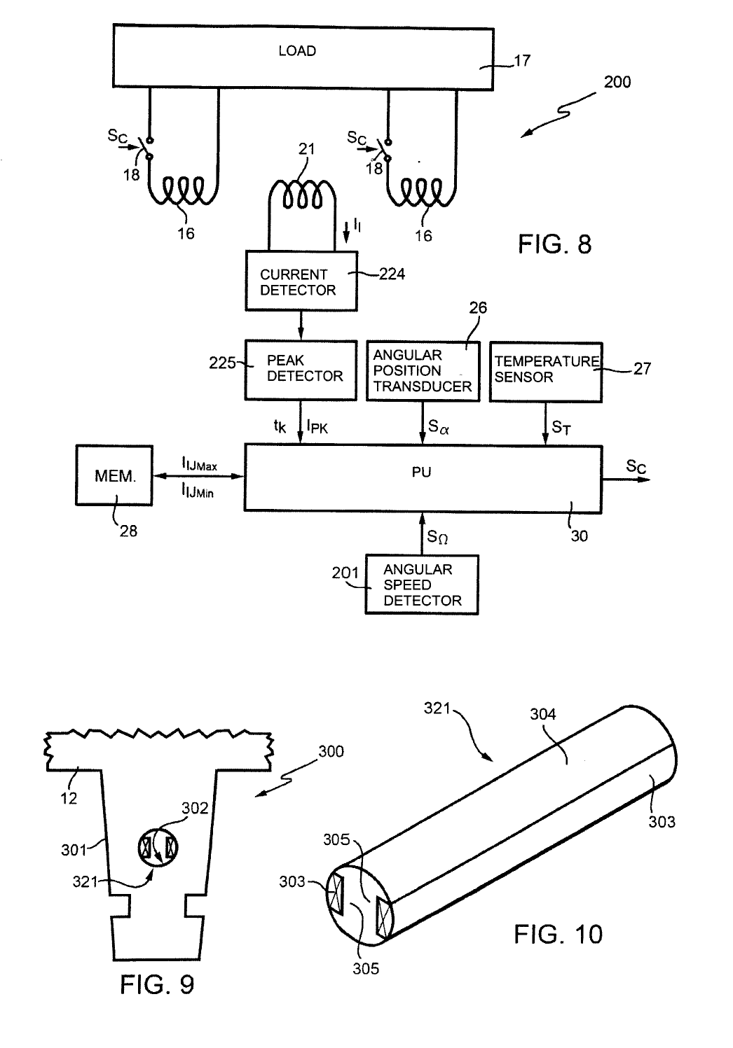

In a further embodiment of the disclosure, shown in FIG. 8, the probe winding 21 of an electric machine 200 is connected to a current detector 224, which detects an induced current II in probe winding 21 in response to passage of a permanent magnet 20. A peak detector 225 receives induced current II and determines its peak values IPK at each half-wave. The peak values IPK and corresponding peak instants tK are supplied to processing unit 30. In this embodiment, memory 28 contains maximum values IIJMax and minimum values IIJMin for peak values IPK of induced current II as a function of the angular speed Ω and temperature T of rotor 13.

In this embodiment, electric machine 200 also comprises an angular speed detector 201 (e.g., a gyroscope, accelerometer, or inclinometer) which supplies processing unit 30 with an angular speed signal SΩ indicating the angular speed Ω of rotor 13.

In the FIG. 9 and 10 embodiment of the disclosure, an electric machine 300 comprises a probe winding 321 housed in a through seat 301 formed in a tooth 302 supporting a stator winding 16. More specifically, through seat 301 is a seat configured to house a stator tie rod configured to grip a portion of stator 12 corresponding to tooth 302. Probe winding 321 is advantageously integrated in a stator tie rod of tooth 302.

Probe winding 321 comprises a conductor 303; and a bar-shaped core 304 made of ferromagnetic material, with a rounded cross section and diametrically opposite longitudinal grooves 305. Conductor 303 is wound longitudinally about core 304 and housed inside grooves 305.

When probe winding 321 is inserted inside tooth 302, its turns are arranged so as to link the magnetic flux generated by rotor 13.

Clearly, changes may be made to the method and electric machine as described herein without, however, departing from the scope of the present disclosure as defined in the accompanying Claims. In particular, more than one probe winding may be used in the same electric machine, and different types of probe windings may be used simultaneously. It should thus be understood that various changes and modifications to the presently disclosed embodiments will be apparent to those skilled in the art. Such changes and modifications can be made without departing from the spirit and scope of the present subject matter and without diminishing its intended advantages. It is therefore intended that such changes and modifications be covered by the appended claims.

1) A method of determining the magnetization level of permanent magnets of an electric machine, the method comprising:
placing a probe winding (21; 121; 321) in an electric machine (6; 100; 200; 300) comprising a stator (12) having a plurality of stator windings (16), and a rotor (13), having a plurality of permanent magnets (20), so that the probe winding (21; 121; 321) is fixed with respect to the stator (12) and links a magnetic flux produced by at least one of the permanent magnets (20);
rotating the rotor (13) at an angular speed (Ω);
detecting an induced electric quantity (V_{I}; I_{I}) at terminals of the probe winding (21; 121; 321) in response to passage of the permanent magnets (20) close to the probe winding (21; 121; 321); and
determining a magnetization level of the permanent magnets (20) on the basis of the induced electric quantity (V_{I}; I_{I}) detected.

2) A method as claimed in claim 1, and comprising setting the stator windings (16) to an open-circuit condition.

3) A method as claimed in claim 1 or 2, wherein determining the magnetization level of the permanent magnets (20) comprises determining peak values (V_{PK}; I_{PK}) of the induced electric quantity (V_{I}; I_{I}) detected; and comparing the peak values (V_{PK}; I_{PK}) with a lower threshold value (V_{IJMin}; I_{IJMin}; and an upper threshold value (V_{IJMax}; I_{IJMax}).

4) A method as claimed in claim 3, wherein determining the magnetization level of the permanent magnets (20) comprises deciding that at least one of the permanent magnets (20) to be defective when one of the peak values (V_{PK}; I_{PK}) is below the lower threshold value (V_{IJMin}; I_{IJMin}) or above the upper threshold value (V_{IJMax}; I_{IJMax}).

5) A method as claimed in claim 4, and comprising identifying a subset of permanent magnets (20) comprising the defective permanent magnet (20).

6) A method as claimed in claim 5, wherein identifying a subset of permanent magnets (20) comprising the defective permanent magnet (20) comprises:
determining an angular position (α) of the rotor (13) at a peak instant (t_{K}) corresponding to the peak value (V_{PK}; I_{PK}) below the lower threshold value (V_{IJMin}; I_{IJMin}) or above the upper threshold value (V_{IJMax}; I_{IJMmax}); and
identifying the permanent magnet (20) closest to the probe winding (21) at the peak instant (t_{K}) on the basis of the angular position (α) of the rotor (13).

7) A method as claimed in any one of claims 3 to 6, wherein determining the magnetization level of the permanent magnets (20) comprises selecting at least one of the lower threshold value (V_{IJMin}; I_{IJMmin}) and the upper threshold value (V_{IJMax}; I_{IJMax}) on the basis of the angular speed (Ω) of the rotor (13).

8) A method as claimed in any one of claims 3 to 7, wherein determining the magnetization level of the permanent magnets (20) comprises determining a temperature (T) of the permanent magnets (20), and selecting at least one of the lower threshold value (V_{IJMin}; I_{IJMin}) and the upper threshold value (V_{IJMax}; I_{IJMax}) on the basis of the temperature (T) of the permanent magnets (20).

9) An electric machine comprising:
a stator (12) having a plurality of stator windings (16);
a rotor (13) having a plurality of permanent magnets (20);
a probe winding (21; 121; 321) fixed with respect to the stator (12) and located close to the rotor (13) to link a magnetic flux produced by at least one of the permanent magnets (20);
a drive member (4, 5, 9, 10) for rotating the rotor (13) at an angular speed (Ω);
detecting means (24; 224) for detecting an induced electric quantity (V_{I}; I_{I}) at terminals of the probe winding (21; 121; 321) in response to passage of the permanent magnets (20) close to the probe winding (21; 121; 321); and
a processing unit (30) configured to determine a magnetization level of the permanent magnets (20) on the basis of the induced electric quantity (V_{I}; I_{I}) detected when the rotor (13) is rotating.

10) An electric machine as claimed in claim 9, and comprising switching means (18) controllable to alternatively connect the stator windings (16) to external electric equipment, and set the stator windings (16) to an open-circuit condition;
and wherein the processing unit (30) is connected to the switching means (18), and is also configured to set the stator windings (16) to an open-circuit condition, and to determine the magnetization level of the permanent magnets (20) on the basis of the induced electric quantity (V_{I}; I_{I}) detected when the rotor (13) is rotating with the stator windings (16) in an open-circuit condition.

11) An electric machine as claimed in claim 9 or 10, wherein the probe winding (321) is housed in a seat (301) formed in a tooth (302) of the stator (12), and comprises:
a bar-shaped core (304) with opposite longitudinal grooves (305); and
a conductor (303) wound about the core (304) and housed in the longitudinal grooves (305).

12) An electric machine as claimed in any one of claims 9 to 11, wherein the probe winding (321) is integrated in a stator tie rod.

13) An electric machine as claimed in any one of claims 9 to 12, and comprising an angular position transducer (26) coupled to the processing unit (30) to supply an angular position signal (S_{α}) indicative of an angular position (α) of the rotor (13); and wherein the processing unit (30) is configured to determine an angular speed (Ω) of the rotor (13) on the basis of the angular position signal (S_{α}).

14) An electric machine as claimed in any one of claims 9 to 12, and comprising an angular speed detecting device (201) coupled to the processing unit (30) to supply an angular speed signal (S_{Ω}) indicative of an angular speed (Ω) of the rotor (13).

15) An electric machine as claimed in claim 13 or 14, and comprising a memory module (28) storing lower threshold values (V_{IJMin}; I_{IJMin}) and upper threshold values (V_{IJMax}; I_{IJMax}) of the induced electric quantity (V_{I}; I_{I}) as a function of the angular speed (Ω) of the rotor (13).

16) An electric machine as claimed in any one of claims 9 to 14, and comprising a temperature sensor (27) for supplying a temperature signal (S_{T}) indicative of a temperature (T) of the rotor (13).

17) An electric machine as claimed in claim 16, and comprising a memory module (28) storing lower threshold values (V_{IJMin}; I_{IJMin}) and upper threshold values (V_{IJMax}; I_{IJMax}) of the induced electric quantity (V_{I}; I_{I}) as a function of the temperature of the rotor (13).
